(19) United States
(12) Patent Application Publication
(10) Pub. No.: US 2020/0120402 A1
(43) Pub. Date: Apr. 16, 2020

(54) MODULE AND METHOD FOR MONITORING POWER

(71) Applicant: D&V Electronics, Ltd., Woodbridge (CA)

(72) Inventors: Veliko Velikov, Woodbridge (CA); Voiko Loukanov, Woodbridge (CA); Ciprian Bacioiu, Woodbridge (CA); Kiril Delidjakov, Woodbridge (CA)

(21) Appl. No.: 16/597,722

(22) Filed: Oct. 9, 2019

Related U.S. Application Data
(60) Provisional application No. 62/745,227, filed on Oct. 12, 2018.

(51) Int. Cl. H04Q 9/00; H04B 3/54; H04L 25/06; G01R 21/133

(52) U.S. Cl. CPC H04Q 9/00; H04B 3/548; H04Q 2209/60; G01R 21/133; H04L 25/06

(57) ABSTRACT

A module and method relating to measuring power supply to a load are described. The module includes a high pass filter corresponding to a first frequency range and configured to communicate a high frequency current signal. The module includes a low pass filter corresponding to a second frequency range configured to communicate a low frequency current signal. A signal combiner is configured to combine the low frequency current signal and the high frequency current signal, thereby generating a combined current signal. A voltage channel is configured to sense a voltage difference across the load and communicate a voltage signal corresponding to the voltage difference across the load. One or more processors in communication with a memory having non-transitory machine readable instructions stored thereon are configured to receive the combined current signal, receive the voltage signal, and determine a power metric based on the combined current signal and the voltage signal.

### CROSS-REFERENCE TO RELATED APPLICATIONS

This application claims priority to Provisional Application No. 62/745,227, entitled Module and Method for Monitoring Power, filed on Oct. 12, 2018, the contents of which are expressly incorporated herein by reference in its entirety.

### FIELD OF THE DISCLOSURE

The embodiments disclosed herein relate to modules and methods for monitoring electric power supplied to electric motors, inverters, and/or other equipment.

### BACKGROUND

Conventional modules and methods for power measurement using two analog-to-digital converters for measuring low-voltage and load current are known. Power measuring units that allow a signal to be plugged into a device and then displayed via software to a screen to the user are also known. Many conventional modules and methods for power measurement are able to measure high frequency current. However, conventional power measurement modules and methods are unable to simultaneously cover the DC range of current. Current power measuring units on the market do not provide a sampling frequency of 10 MHz, for example, which limits the ability of these units to analyze harmonics created during various control techniques used to control automotive electric motors (among other limitations).

### SUMMARY

One aspect of the disclosure relates to a power measurement module for measuring power supply to a load via a power line. The power measurement module includes a high pass filter corresponding to a first frequency range and configured to communicate a high frequency current signal from a first position of the power line. The power measurement module includes a low pass filter corresponding to a second frequency range and configured to communicate a low frequency current signal from a second position of the power line. A signal combiner is configured to combine the low frequency current signal and the high frequency current signal thereby generating a combined current signal. A voltage channel is configured to sense a voltage difference across the load and communicate a voltage signal corresponding to the voltage difference across the load. The power measurement module includes one or more processors in communication with a memory having non-transitory machine readable instructions stored thereon. The one or more processors are configured to receive the combined current signal, receive the voltage signal, and determine a power metric based on the combined current signal and the voltage signal.

In some embodiments of the power measurement module, the high frequency current signal and the low frequency current signal are combined into a single current signal. In some embodiments, the single current signal is digitized utilizing a first analog-to-digital converter (ADC), and wherein the voltage signal is digitized using a second ADC. In some embodiments, the first range corresponds to a cutoff frequency and a maximum frequency and the second range corresponds to frequencies less than the cutoff frequency. In some embodiments, the housing comprises a high frequency port, a low frequency port, a voltage port, and a patch panel port. In some embodiments, the patch panel port provides a raw signal configured for display by an external scope. In some embodiments, the power measurement module is configured to sample the power in the power line at a frequency corresponding to 10 MHz.

In some embodiments, the power measurement module is configured for power measurements associated with electric motors and inverters. In some embodiments, the first position differs from the second position. In some embodiments, the power metric includes one or more of: watt-hour (Wh), kilowatt-hour (kWh), joules (j), kilojoules (kj), power efficiency, kilo volt-ampere (KVA), kilo volt-ampere reactive (kVAR), amperes, voltage, root mean square (RMS) voltage, peak RMS voltage, real power P, reactive power Q, complex and apparent power, power factor, frequency, waveform, or phase angle. In some embodiments, the one or more processors are further configured to output command and/or control signals in response at least in part to the high frequency current signal, the low frequency current signal, or the voltage channel signal.

Another aspect of the disclosure relates to a method for measuring power supplied to a load via a power line utilizing a power measurement module. The power measurement module includes a high pass filter corresponding to a first frequency range, a low pass filter corresponding to a second frequency range, a signal combiner, a voltage channel, and one or more processors in communication with a memory having non-transitory machine readable instructions stored thereon. The method for measuring power includes communicating, utilizing the high-pass filter, a high frequency current signal from a first position of the power line. The method continues by communicating, utilizing the low-pass filter, a low frequency current signal from a second position of the power line and combining, utilizing the signal combiner, the low frequency current signal and the high frequency current signal, thereby generating a combined current signal. In order to measure power supply to the load method requires determining, utilizing the voltage channel, a voltage difference across the load, and communicating a voltage signal corresponding to the voltage difference across the load. The method concludes by determining, utilizing the one or more processors, a power metric based on the combined current signal and the voltage signal.

In some embodiments, the method includes combining the high frequency current signal and the low frequency current signal into a single current signal. In some embodiments, the single current signal is digitized utilizing a first analog-to-digital converter (ADC), and the voltage signal is digitized using a second ADC. In some embodiments, the first range corresponds to a cutoff frequency and a maximum frequency and the second range corresponds to frequencies less than the cutoff frequency. In some embodiments of the method, the power measurement module comprises a housing, and wherein the housing comprises a high frequency port, a low frequency port, a voltage port, and a patch panel port. In some embodiments, the patch panel port provides a raw signal configured for display by an external scope. In some embodiments, method includes sampling the power in the power line at a frequency corresponding to 10 MHz. In some embodiments, the method includes power measurements associated with electric motors and inverters. In some embodiments, the first position differs from the second position. In some embodiments, the method includes measuring the power metric using one or more of: watt-hour (Wh), kilowatt-hour (kWh), joules (j), kilojoules (kj), power efficiency, kilo volt-ampere (KVA), kilo volt-ampere reactive (kVAR), amperes, voltage, root mean square (RMS) voltage, peak RMS voltage, real power P, reactive power Q, complex and apparent power, power factor, frequency, waveform, or phase angle. In some embodiments, the method includes outputting command and/or control signals in response at least in part to the high pass filter signal, the low pass filter signal, or the voltage channel signal.

### BRIEF DESCRIPTION OF THE DRAWINGS

FIG. 1 illustrates a schematic for a power measurement module, in accordance with one or more embodiments;

FIGS. 2A-2B illustrate a front view and side view of the power measurement module depicting physical dimensions and connector locations of a power measurement module housing, in accordance with one or more embodiments;

FIG. 3 illustrates a schematic for a power measurement module, in accordance with one or more implementations;

FIG. 4 illustrates a connector for use in a power measurement module, in accordance with one or more embodiments;

FIGS. 5A-5B illustrates a 96-pin connector for use in a power measurement module, in accordance with one or more embodiments; and

FIG. 6 illustrates a main board of the power measurement module, in accordance with one or more embodiments.

### DETAILED DESCRIPTION OF EXEMPLARY EMBODIMENTS

The present invention will now be described in detail with reference to the drawings, which are provided as illustrative examples of the invention to enable those skilled in the art to practice the invention. Notably, the figures and examples below are not meant to limit the scope of the present invention to a single embodiment, but other embodiments are possible by way of interchange of some or all of the described or illustrated elements.

Moreover, where certain elements of the present invention can be partially or fully implemented using known components, only those portions of such known components that are necessary for an understanding of the present invention will be described, and detailed descriptions of other portions of such known components will be omitted so as not to obscure the invention. As used herein, the singular form of “a”, “an”, and “the” include plural references unless the context clearly dictates otherwise. As used herein, the statement that two or more parts or components are “coupled” shall mean that the parts are joined or operate together either directly or indirectly (i.e., through one or more intermediate parts or components, so long as a link occurs).

Embodiments described as being implemented in hardware should not be limited thereto, but can include embodiments implemented in software, or combinations of software and hardware, and vice-versa, as will be apparent to those skilled in the art, unless otherwise specified herein. In the exemplary embodiments described herein, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

As used herein, “directly coupled” means that two elements are directly in contact with each other. As used herein, “fixedly coupled” or “fixed” means that two components are coupled to move as one while maintaining a constant orientation relative to each other. As used herein, “operatively coupled” means that two elements are coupled in such a way that the two elements function together. It is to be understood that two elements “operatively coupled” does not require a direct connection or a permanent connection between them.

As used herein, the word “unitary” means a component is created as a single piece or unit. That is, a component that includes pieces that are created separately and then coupled together as a unit is not a “unitary” component or body. As employed herein, the statement that two or more parts or components “engage” one another shall mean that the parts exert a force against one another either directly or through one or more intermediate parts or components. As employed herein, the term “number” shall mean one or an integer greater than one (i.e., a plurality). Directional phrases used herein, such as, for example and without limitation, top, bottom, left, right, upper, lower, front, back, and derivatives thereof, relate to the orientation of the elements shown in the drawings and are not limiting upon the claims unless expressly recited therein.

One or more embodiments described herein relate to a power measurement module configured for wideband active and reactive power measurement. The power measurement module utilizes two current sensors, combined to form a single, highly accurate and wideband width channel for a current analog-to-digital converter (ADC). The two measurements provided by the two current sensors are combined during a power calculation in order to determine a power measurement of the load.

The frequency range of high precision current sensors is limited to below the real spectrum of the current signal. Power measuring modules having current sensors which are able to measure the high frequency current accurately are often unable to cover the DC range of the current. Accordingly, one or more embodiments described herein utilize two independent current sensors. The first independent current sensor may be configured for low frequencies from 0 Hz up to a cutoff frequency of the sensor. The second independent current sensor may be configured for high frequencies, such as from the cutoff frequency to a maximum frequency. One or more embodiments described herein may combine the signals from the two current sensors into a single channel. The signal channel may then be digitized. Accordingly, in one embodiment, the two current sensor signals are shaped by a low-pass filter (LPF) for the first current sensor and a high pass filter (HPF) for the second current sensor, which are added and applied to an analog-to-digital converter.

Conventional power measuring units on the market do not provide the sampling frequency of 10 MHz. This limitation inhibits the ability to analyze harmonics created during various control techniques used to control automotive electric motors.

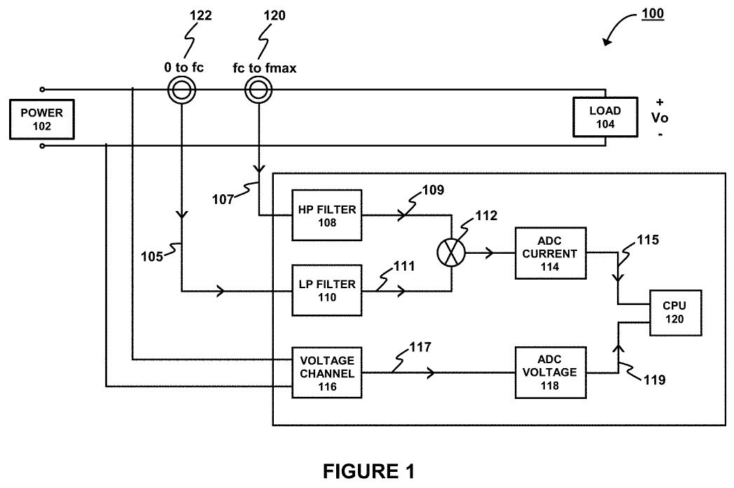

Referring now to FIG. 1, FIG. 1 depicts power measurement module (PMM) 100 in accordance with one or more embodiments. Power measurement module 100 may include power source 102 and load 104. In some embodiments, PMM 100 may include high-pass filter (HPF) 108, low-pass filter (LPF) 110, signal combiner 112, current ADC 114, voltage channel 116, voltage ADC 118, CPU 120, and/or other components.

As shown in FIG. 1, power source 102 may be configured to supply power (i.e., an electric current) to a load 104. In some embodiments, load 104 may include electric motor and/or inverter. In one embodiment, power source 102 may supply a 10 MHz alternating current. In another embodiment, power source 102 may be configured to supply alternating currents in the range of 10 MHz through 100 MHz.

As further shown in FIG. 1, PMM 100 monitors the current flowing to load 104 from power source 102. PMM 100 may include high pass filter 108. HPF 108 may be coupled to high-pass filter node 120. HPF 108 communicates a high frequency current signal from a first position of the power line, for example, at node 120. In some embodiments, HPF 108 may be configured to pass frequencies corresponding to or between a cutoff frequency and a maximum frequency. In one embodiment, the cutoff frequency may include 10 MHz and the maximum frequency may include up to 100 MHz. In another embodiment, the cutoff frequency may include 20 MHz and the maximum frequency may include up to 200 MHz. In some embodiments, HPF 108 may have a corresponding low frequency current connector, which is discussed in further detail below. As shown in FIG. 1, HPF 108 may be configured to filter the high frequency current, e.g., between the cutoff frequency and the maximum frequency, and output the filtered high-frequency current to signal combiner 112.

In some embodiments, PMM 100 may include low-pass filter 110. Low pass filter 110 may be configured to pass frequencies corresponding to frequencies less than the cutoff frequency. In one embodiment, the cutoff frequency may include 10 MHz. In another embodiment, the cutoff frequency may be between 10 MHz and 100 MHz. Low pass filter 110 may communicate a low frequency current signal from a second position of the power line, for example node 122. In some embodiments, LPF 110 may include a corresponding low frequency current connector, which is discussed in further detail below. As shown in FIG. 1, LPF 110 may be configured to filter the low frequency current (e.g., by passing frequencies less than the cutoff frequency), and output the filtered low-frequency current to signal combiner 112.

In some embodiments, PMM 100 may include signal combiner 112. As shown in FIG. 1, low-pass filter 110 and HP filter 108 may transmit their respective filtered low frequency and high-frequency current signals to signal combiner 112. Signal combiner 112 may receive and combine filtered low frequency current signal 111 and filtered high frequency current signal 109, thereby generating a combined current signal 113. In some embodiments, signal combiner 112 may output combined current signal 113 to ADC 114. Combined single current signal 113 may then be digitized utilizing ADC 114. After having digitized combined current signal 113, ADC 114 transmits digitized combined current signal 115 to CPU 120 for processing, which is discussed in further detail below.

In some embodiments, PMM 100 includes voltage channel 116. Voltage channel may be 116 configured to sense a voltage potential difference, Vo, across load 104. In some embodiments, as discussed in further detail below, voltage channel 116 may operate with a corresponding high-voltage adapter connector (not shown). The high-voltage adapter connector may provide a connection for a PMM 100 high-voltage adapter. The adapter accepts voltages up to 1000 V and divides the voltage to pass a maximum of 5 V through the high-voltage adapter connector, for example.

Voltage channel 116 communicates Vo via voltage signal 117. In some embodiments, voltage signal 117 may be digitized utilizing ADC 118. As shown in FIG. 1, voltage ADC 118 may be configured to receive and digitize voltage signal 117, thereby outputting a digitized voltage signal 119. Voltage ADC 118 then transmits a digitized voltage signal 119 to CPU 120 for processing, which is discussed in further detail below.

In some embodiments, PMM 100 includes CPU 120. CPU 120 may include one or more processor(s) and/or processing circuitry (not shown) that are configured to provide information processing and/or system control capabilities for PMM 100. In some embodiments, processors of CPU 120 may include one or more of a digital processor, an analog processor, a digital circuit designed to process information, an analog circuit designed to process information, a state machine, a field programmable gate array (FPGA), and/or other mechanisms for electronically processing information. or more processors in communication with a memory (not shown) having non-transitory machine readable instructions stored thereon. In some embodiments, CPU 120 may include one or more storage buffers, data registers, latches, CMOS inverters, interrupt/polling circuitry, timestamping circuitry, and/or other solid-state circuitry configured to receive and process raw data from sensors 120, 122, and communicate sensor data for processing and storage

In some embodiments, the one or more processors may be configured to receive the combined current signal, receive the voltage signal, and determine a power metric based on the combined current signal and the voltage signal. In some embodiments, the power metric may be expressed as a function of one or more of: watt-hour (Wh), kilowatt-hour (kWh), joules (j), kilojoules (kj), power efficiency, kilo volt-ampere (KVA), kilo volt-ampere reactive (kVAR), amperes, voltage, root mean square (RMS) voltage, peak RMS voltage, real power P, reactive power Q, complex and apparent power, power factor, frequency, waveform, phase angle., and the like.

One or more embodiments described herein provide for PMM 100 determining a power metric corresponding to the complete power spectrum of the power signal supplied by power source 102. Generally, the frequency range of high precision current sensors are limited to below the real spectrum of the current signal. However, by combining inputs from two independent current sensors (e.g., HPF 108 and LPF 110) the exemplary embodiments described herein are able to measure high sampling rates while maintaining a high accuracy, for example as depicted by Table 1 below.

TABLE 1
PMM Accuracies and Sampling Frequencies

| | | S. Frequency | S. Frequency |
|---|---|---|---|
| Connection | Accuracy | (continuous) | (snapshot) |
| CN400: | ±0.1% | Equiv. 200 kHz | 10 MHz |
| Voltage | | (50samples@10 MHz avg.) | |
| CN500: Low | ±0.1% | Equiv. 200 kHz | 10 MHz |
| Frequency | | (50samples@10 MHz avg.) | |
| Current | | | |
| CN501: High | ±0.1% | Equiv. 200 kHz | 10 MHz |
| Frequency | | (50samples@10 MHz avg.) | |
| Current | | | |

In some embodiments, CPU 120 may be configured to receive digitized combined current signal 115 and digitized voltage signal 119 and determine a power metric based on digitized combined current signal 115 and digitized voltage signal 119. In some embodiments, prior to determining the power metric, CPU 120 may be configured to employ one or more signal processing techniques to condition signal 115, 119. For example, CPU 120 may be configured to implement a smoothing function on signals 115, 119 in order to remove high-frequency noise and low-frequency artifact that may be present in signals 115, 119. Utilizing two independent current sensors as discussed above, provides the ability to analyze harmonics created during various control techniques used to control automotive electric motors and/or other components. Accordingly, in one embodiment, PMM 100 may be configured for data acquisition of measurements associated with the evaluation of electric motors and inverters, for example.

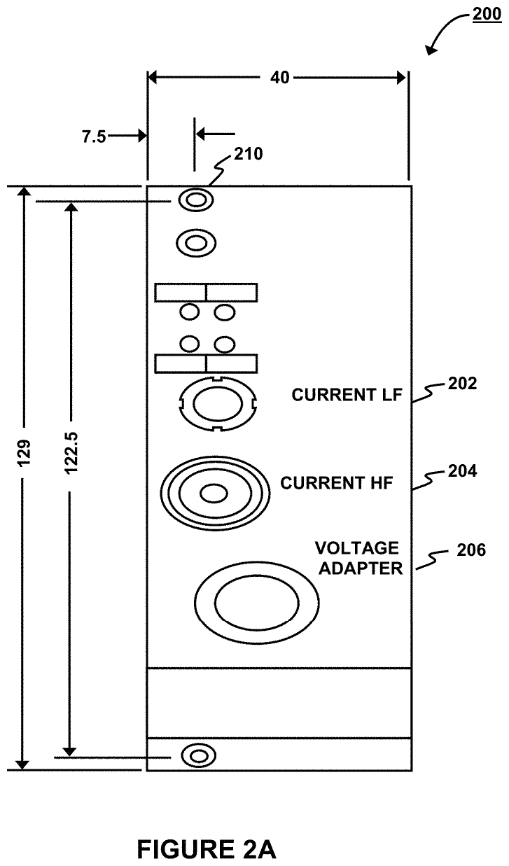

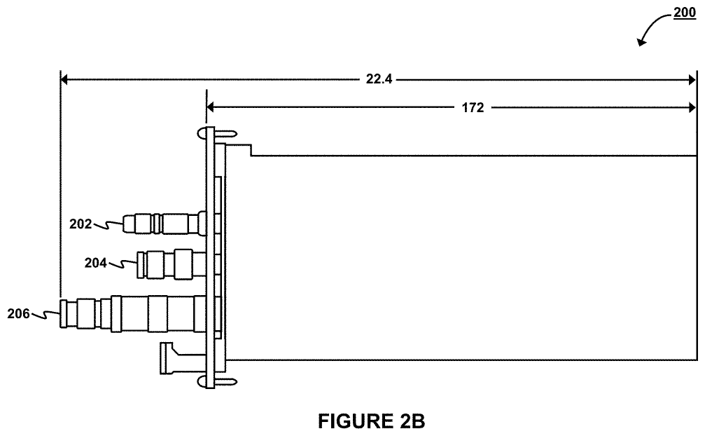

Referring now to FIGS. 2A-2B, FIG. 2A in conjunction with FIG. 2B depicts a PMM housing 200. As shown, PMM housing 200 includes low-frequency current connector 202, high-frequency current connector 204, voltage adapter 206, LED indicators 208, and fasteners 210. Fasteners 210 may be a screw, a rivet, a clasp, a latch, a snap, or any other mechanism capable of holding PMM housing 200 in position on a surface. For example, in one embodiment, fastener 210 may include a plurality of fasteners each formed with a threaded post and a nut.

In some embodiments, fasteners 210 may be positioned 7.5 (for example) inches from either edge of PMM housing 200. Fasteners 210 may be spaced apart 122.5 (for example) inches on the top and bottom of PMM housing 200. In some embodiments, PMM housing 200 may have a width of 40 (for example) inches, a height of 129 (for example) inches and a depth of 224 (for example) inches. In some embodiments, PMM housing 200 includes a depth of 172 (for example) inches not including connectors 202, 204, 206. In another embodiment, any other form of fastener, in any other position capable of coupling PMM housing 200 to a surface may be used. As such, the example dimensions described above are not intended to be limiting. The present device may have any dimensions that allow it to function as described herein.

In some embodiments, low-frequency current connector 202 may be configured to receive a low-frequency current signal (e.g., low-frequency current 105 of FIG. 1). In one embodiment, low-frequency current connector 202 may correspond to a 4 pin LEMO connector that may be configured to supply power to current sensing devices (e.g., current sensing devices at nodes 120, 122 of FIG. 1) and to receive current input. A voltage is created depending on the values of resistors employed in low-frequency current connector 202. The values of the resistors may be set such that the input voltage does not exceed 1.1329 V in magnitude.

In some embodiments, PMM housing 200 includes a high-frequency current connector 204. In one embodiment, high-frequency current connector 204, may include a BNC connection that may be used in conjunction with one or more Rogowski sensors. In one embodiment, the high-frequency current connector 204 channel performs signal conditioning of high-frequency signals.

In some embodiments, PMM housing 200 includes high voltage adapter connection 206. High voltage adapter connection 206 may be configured to accept voltages of up to 1000 V, for example. In some embodiments, high voltage adapter connection 206 may be configured to accept voltages of higher than 1000 V. High voltage adapter connection 206 may be configured to divide a high voltage input and output a maximum of 5 V, for example.

In some embodiments, PMM housing 200 includes a patch panel port (not shown). The patch panel port provides a raw signal to be displayed by an external scope (i.e. separate from PMM housing 200) and provides signal access to PMM 100. The external scope may include a spectrum analyzer, an oscilloscope, a signal generator, a voltmeter, an ohmmeter, and/or any other device configured to receive and display an electromagnetic signal. PMM 100 and PMM housing 200 may be configured to allow the signal to be plugged into an external device and then displayed via software or screen to the user. PMM 100, in accordance with one or more embodiments, includes a patch panel port that allows the raw signal to not only be displayed on software but also be available to be viewed with the external scope for comparison purposes. In some embodiments, PMM 100, 200 may include electrical specifications similar to or the same as Table 2 below.

TABLE 2
PMM Electrical Specifications

| Rating | Min | Typ. | Max | Unit |
|---|---|---|---|---|
| Module Supply Voltage | −15 | | +15 | VDC |
| Module Supply Current | | | 3.4 | A |
| Operating Voltage, peak | −15 | | +15 | V |
| Operating Current, peak | 1 | | 2 | A |
| Bus Termination Voltage | | 3.3 | | VDC |
| Bus Termination Current | | 2 | 2.4 | A |
| Analog In voltage | −10 | | +10 | VDC |
| Operating Temperature | 5 | 25 | 40 | ° C. |
| Operating Humidity | | | 80 | % |

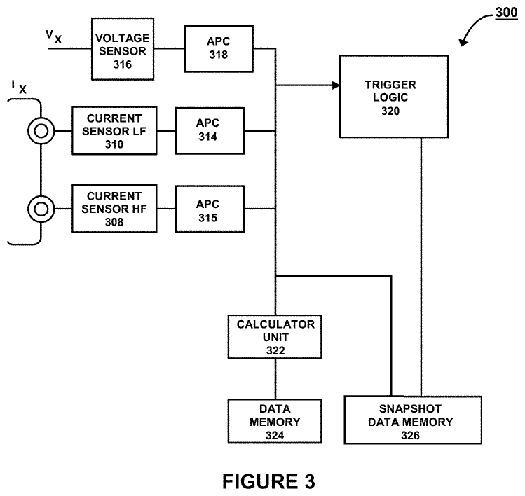

Referring now to FIG. 3, FIG. 3 depicts an exemplary PMM 300 in accordance with one or more embodiments. PMM 300 may correspond to PMM 100 of FIG. 1, of which similarly labeled parts and numbers correspond to similar functionality. In some embodiments, PMM 300 may include voltage sensor 316, low-frequency current sensor 310, high-frequency current sensor 308, ADC 314, 315, 318, trigger logic 320, calculation unit 322, data memory 324, and snapshot data memory 326. PMM 300 differs from PMM 100 of FIG. 1 in that the high-frequency current and the low-frequency current are not combined into a combined current signal. Rather, PMM 300 employs individual ADCs (e.g., ADC 314 and ADC 315) for each respective current sensor signal 310, 308. As shown in FIG. 3, low-frequency current sensor 310, and high-frequency current sensor 308 may each be configured to output their respective signal to trigger logic 320, calculation unit 322, and snapshot data memory 326. Calculation unit 322 may be configured to determine power metrics related to power consumption of the load (not shown in FIG. 3). Upon determining the power metrics, calculation unit 322 may be configured to transmit one or more power metrics for storage in data memory 324.

In some embodiments, calculation unit 322, and/or trigger logic 320 may include one or more processor(s) and/or processing circuitry (not shown) that may be configured to provide information processing and/or system control capabilities for PMM 100, 200, 300. In some embodiments, processors may include one or more of a digital processor, an analog processor, a digital circuit designed to process information, an analog circuit designed to process information, a state machine, a field programmable gate array (FPGA), and/or other mechanisms for electronically processing information.

In some embodiments, memory 324, may include (not shown) non-transitory machine-readable instructions configured for executing the exemplary embodiments described herein. Non-transitory machine readable instructions may include program instructions in source code, object code, firmware, executable code or other formats for performing the exemplary embodiments described herein. In some embodiments, memory 124, 324 may include conventional computer system RAM (random access memory), ROM (read only memory), EPROM (erasable, programmable ROM), EEPROM (electrically erasable, programmable ROM), Flash memory, and/or magnetic or optical disks or tapes, and/or any other electronic storage medium capable of storing non-transitory machine readable instructions.

In some embodiments, trigger logic 320 may be configured to receive output signals from sensors 308, 310, 316 and employ trigger logic functionality. For example, trigger logic 320 may be configured to output command and/or control signals in response at least in part to high frequency current signal 109, low frequency current signal 111, or voltage channel signal 117. In some embodiments, an additional input signal may be reserved for including further functionality. In some embodiments, output signals 308, 310, and 316 may correspond to signals S0, S1, and S2, respectively (see Table 3 below).

TABLE 3
Trigger Logic 320 showing input
logic and output command function

Logic*

| S₃ | S₂ | S₁ | S₀ | Function |
|---|---|---|---|---|
| 0 | 0 | 0 | 0 | PMM Slice is instance 1 |
| 0 | 0 | 0 | 1 | PMM Slice is instance 2 |
| 0 | 0 | 1 | 0 | PMM Slice is instance 3 |
| 0 | 0 | 1 | 1 | PMM Slice is instance 4 |
| 0 | 1 | 0 | 0 | PMM Slice is instance 5 |
| 0 | 1 | 0 | 1 | PMM Slice is instance 6 |
| 0 | 1 | 1 | 0 | PMM Slice is instance 7 |
| 0 | 1 | 1 | 1 | PMM Slice is instance 8 |
| 1 | X | X | X | Currently an invalid configuration** |

In some embodiments, trigger logic 320 may receive four (4) input signals S0-S3. Each signal S0-S3 may be received eithers as a signal high (1) or signal low (0), or a “do not care” condition (x). Based on the particular logic received trigger logic 320 may actuate PMM slice instance 1-8 as shown above in Table 3. In this example, signal S3 may be utilized to execute additional command and control functionality. However, this example is not intended to be limiting.

In some embodiments, trigger logic 320 may output command and control operations corresponding to calculation unit 322, data memory 324 and/or snapshot data memory 326. Such command and control operations may be utilized for actuating memory and calculation functionality in accordance with one or more embodiments described herein. For example, trigger logic may input and output command signals operations, for example, as shown below in Table 3.

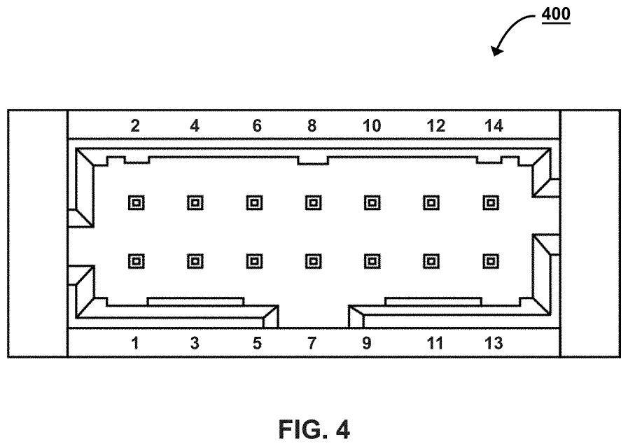

Referring now to FIG. 4, FIG. 4 depicts an exemplary connector 400. In some embodiments, connector 400 may be identified as CN1:JTAG. As discussed below, PMM 100, 200, 300 includes multiple connections to allow access to CPU 120 and/or trigger logic 320. In some embodiments, the multiple connectors and corresponding connector part number may correspond to Table 4 below.

TABLE 4
Connector Part Numbers

| Name | P/N | Mating P/N | Housing P/N |
|---|---|---|---|
| CN1: JTAG | 210-0544 | Mates with connector that | |
| | | comes with the | |
| | | corresponding device | |
| | | programmer | |
| CN3: PMM | 210-1560 | Mates with CN on the main | |
| Connect | | PMM board | |
| CN400: High | 210-0224 | 210-0013 | |
| Voltage | | | |
| Adapter | | | |
| P500: Low | 210-1557 | 210-1556 | N/A |
| Frequency | | | |
| Current | | | |
| P501: High | 210-1551 | 210-1554 | N/A |
| Frequency | | | |
| Current | | | |

In some embodiments, connector 400 (e.g., CN1: JTAG)—may include pin connections according to:

| | |
|---|---|
| 1. | GND; |
| 2. | +2.5 V; |
| 3. | GND |
| 4. | TMS |
| 5. | GND |
| 6. | TCK |
| 7. | GND |
| 8. | TDO |
| 9. | GND |
| 10. | TDI |
| 11. | GND |
| 12. | NC |
| 13. | GND |
| 14. | NC |

CN400: High voltage adapter—may include pin connections according to:

| | |
|---|---|
| 1. | 1. rTP401 |
| 2. | 2. rTP402 |
| 3. | 3. GND |
| 4. | 4. GND |
| 5. | 5. TP400 (U+ from adapter) |
| 6. | 6. TP401 (U− from adapter) |
| 7. | 7. rTP400 |
| 8. | 8. −AVDDu |
| 9. | 9. +AVDDu |
| 10. | 10. GND |

P500: Low-Frequency current—may include pin connections according to:

| | |
|---|---|
| 1. | 1. Current In |
| 2. | 2. Current Out |
| 3. | 3. Bus Positive |
| 4. | 4. Bus Negative |

P501: High-Frequency current—may include pin connections according to:

| | |
|---|---|
| 1. | 1. Rogowski sensor |
| 2. | 2. GND |

In some embodiments, CN1:JTAG may include a connection to allow access to a FPGA (e.g. 120, 320). CN3:PMM connect may include a connection to the main PMM board (e.g. board 600, described below). CN400: High Voltage Adapter may include a connection for a high voltage adapter, which may accept voltages of up to 1000V and divide the voltage to pass a maximum of 5V through the CN400 connection. In some embodiments, P500 low frequency current connector may include a 4-pin LEMO connector to supply power to the current sensing devices (e.g., 109, 110). In some embodiments, a voltage is created such that the input voltage does not exceed 1.1329V.

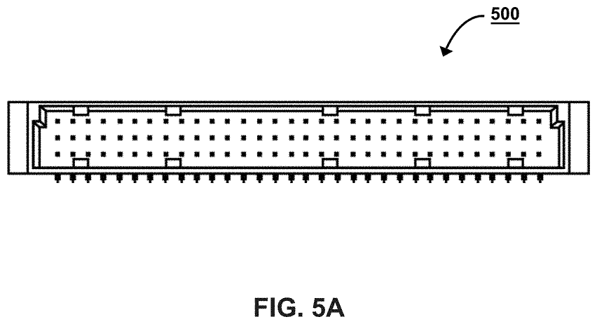

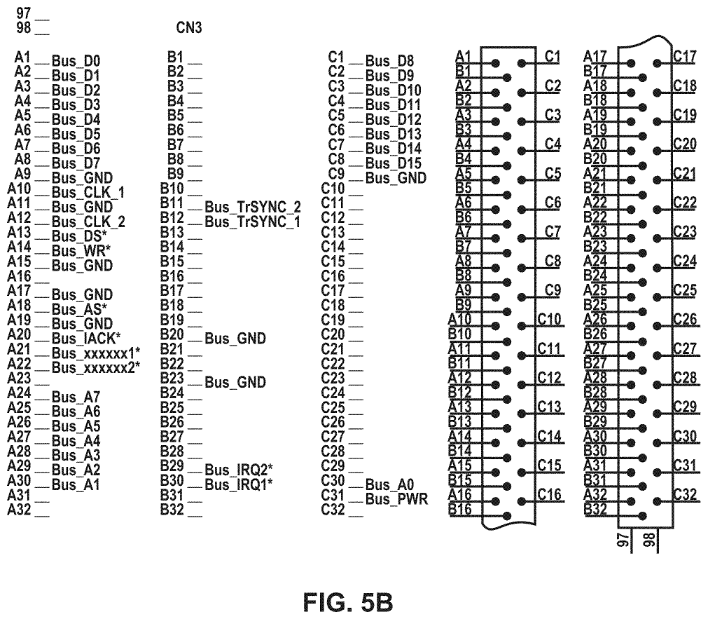

Referring now to FIGS. 5A and 5B, FIG. 5A depicts an exemplary FPGA 500 and FIG. 5B depicts exemplary connector pinouts corresponding to FPGA 500 of FIG. 5A, which may be utilized PMM 100, 200, 300, in accordance with one or more embodiments described herein. For example, FPGA 500 may correspond to CN3: PMM connector as discussed in Table 4 above. In some embodiments, FPGA 500 may include 96-pin connector to connect a slice to the main PMM board as shown in FIG. 5B.

In some embodiments, PMM 100, 200, 300 may consist of multiple cards or slices that comprise, for example, look-up tables (LUTs) as shown above in Table 3. Individual slices may be configured as one or more programmable logic blocks. Programmable logic blocks may include arithmetic logic, registers, LUTs, latches, flip-flops, multiplexers, and the like. Elements organized in programmable logic blocks share connections in order to utilize fast carry chains, thereby increasing efficiency. In some embodiments, programmable logic blocks may be configured for measuring various qualitative values of PMM 100, 200, 300. For example, programmable logic blocks may measure voltage and current, analogue inputs, positions signals, and/or various other measurement corresponding to one or more embodiments described herein.

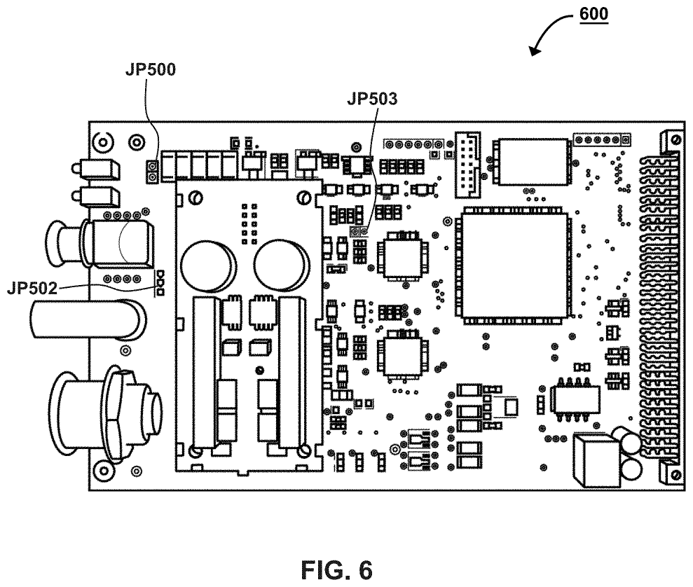

Referring now to FIG. 6, FIG. 6 illustrates an exemplary main PMM board 600 of PMM 100, 200, 300 in accordance with one or more embodiments described herein. As shown in FIG. 6, PMM board 600 may include Jumpers JP500, JP502, and JP503. In some embodiments, Jumpers JP500 and JP502 may be implemented for specifying the ground reference point of the measuring current (e.g., signal 115). If a ground is provided within the sensor (e.g., 108, 110, 116) then JP502 is to be closed and JP500 is to be open. When the circuit must be grounded within tester equipment that PMM 100, 200, 300 may be integrated with, for example, JP500 is to be closed and JP502 is to be open. Implementing jumpers in this fashion increases accuracy of power measurement readings.

In the claims, any reference signs placed between parentheses shall not be construed as limiting the claim. The word “comprising” or “including” does not exclude the presence of elements or steps other than those listed in a claim. In a device claim enumerating several means, several of these means may be embodied by one and the same item of hardware. The word “a” or “an” preceding an element does not exclude the presence of a plurality of such elements. In any device claim enumerating several means, several of these means may be embodied by one and the same item of hardware. The mere fact that certain elements are recited in mutually different dependent claims does not indicate that these elements cannot be used in combination.

Although the description provided above provides detail for the purpose of illustration based on what is currently considered to be the most practical embodiments, it is to be understood that such detail is solely for that purpose and that the disclosure is not limited to the expressly disclosed embodiments, but, on the contrary, is intended to cover modifications and equivalent arrangements that are within the spirit and scope of the appended claims. For example, it is to be understood that the present disclosure contemplates that, to the extent possible, one or more features of any embodiment can be combined with one or more features of any other embodiment.

What is claimed is:

1. A power measurement module for measuring power supplied to a load via a power line, the module comprising:
a high pass filter corresponding to a first frequency range configured to communicate a high frequency current signal from a first position on the power line;
a low pass filter corresponding to a second frequency range configured to communicate a low frequency current signal from a second position on the power line;
a signal combiner configured to combine the low frequency current signal and the high frequency current signal thereby generating a combined current signal;
a voltage channel configured to sense a voltage difference across the load and communicate a voltage signal corresponding to the voltage difference across the load; and
one or more processors in communication with a memory having non-transitory machine readable instructions stored thereon, the one or more processors configured to:
receive the combined current signal;
receive the voltage signal; and
determine a power metric based on the combined current signal and the voltage signal.

2. The power measurement module of claim 1, wherein the high frequency current signal and the low frequency current signal are combined into a single current signal.

3. The power measurement module of claim 2, wherein the single current signal is digitized utilizing a first analog-to-digital converter (ADC), and wherein the voltage signal is digitized using a second ADC.

4. The power measurement module of claim 1, wherein the first range corresponds to a cutoff frequency and a maximum frequency.

5. The power measurement module of claim 1, wherein the second range corresponds to frequencies less than the cutoff frequency.

6. The power measurement module of claim 1, wherein the power measurement module comprises a housing, wherein the housing comprises a high frequency port, a low frequency port, a voltage port, and a patch panel port.

7. The power measurement module of claim 6, wherein the patch panel port provides a raw signal configured for display by an external scope.

8. The power measurement module of claim 1, wherein the power measurement module is configured to sample the power in the power line at a frequency corresponding to 10 MHz.

9. The power measurement module of claim 1, wherein the power measurement module is configured for power measurements associated with electric motors and inverters.

10. The power measurement module of claim 1, wherein the first position differs from the second position.

11. The power measurement module of claim 1, wherein the power metric includes one or more of: watt-hour (Wh), kilowatt-hour (kWh), joules (j), kilojoules (kj), power efficiency, kilo volt-ampere (KVA), kilo volt-ampere reactive (kVAR), amperes, voltage, root mean square (RMS) voltage, peak RMS voltage, real power P, reactive power Q, complex and apparent power, power factor, frequency, waveform, or phase angle.

12. The power measurement module of claim 1, wherein the one or more processors are further configured to output command and/or control signals in response at least in part to the high frequency current signal, the low frequency current signal, or the voltage channel signal.

13. A method for measuring power supplied to a load via a power line utilizing a power measurement module, the power measurement module comprising a high pass filter corresponding to a first frequency range; a low pass filter corresponding to a second frequency range; a signal combiner; a voltage channel; and one or more processors in communication with a memory having non-transitory machine readable instructions stored thereon, the method comprising:
communicating, utilizing the high-pass filter, a high frequency current signal from a first position of the power line;
communicating, utilizing the low-pass filter, a low frequency current signal from a second position of the power line;
combining, utilizing the signal combiner, the low frequency current signal and the high frequency current signal, thereby generating a combined current signal;
determining, utilizing the voltage channel, a voltage difference across the load;
communicating a voltage signal corresponding to the voltage difference across the load; and
determining, utilizing the one or more processors, a power metric based on the combined current signal and the voltage signal.

14. The method of claim 13, wherein the high frequency current signal in the low frequency current signal are combined into a single current signal

15. The method of claim 14, wherein the single current signal is digitized utilizing a first analog-to-digital converter (ADC), and wherein the voltage signal is digitized using a second ADC.

16. The method of claim 13, wherein the first range corresponds to a cutoff frequency and a maximum frequency.

17. The method of claim 13, wherein the second range corresponds to frequencies less than the cutoff frequency.

18. The method of claim 13, wherein the power measurement module comprises a housing, and wherein the housing comprises a high frequency port, a low frequency port, a voltage port, and a patch panel port.

19. The method of claim 18, wherein the patch panel port provides a raw signal configured for display by an external scope.

20. The method of claim 13, wherein the power measurement module is configured to sample the power in the power line at a frequency corresponding to 10 MHz.

21. The method of claim 13, wherein the power measurement module is configured for power measurements associated with electric motors and inverters.

22. Method of claim 13, wherein the first position differs from the second position.

23. The method of claim 13, wherein the power metric includes one or more of: watt-hour (Wh), kilowatt-hour (kWh), joules (j), kilojoules (kj), power efficiency, kilo volt-ampere (KVA), kilo volt-ampere reactive (kVAR), amperes, voltage, root mean square (RMS) voltage, peak RMS voltage, real power P, reactive power Q, complex and apparent power, power factor, frequency, waveform, or phase angle.

24. The method of claim 13, wherein the one or more processors are further configured to output command and/or control signals in response at least in part to the high pass filter signal, the low pass filter signal, or the voltage channel signal
